(19) United States
(12) Patent Application Publication
(10) Pub. No.: US 2026/0047141 A1
(43) Pub. Date: Feb. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Zong-Han Lin, Tainan City (TW)

(73) Assignee: UNITED MICROELECTRONICS CORP., Hsin-Chu City (TW)

(21) Appl. No.: 18/885,737

(22) Filed: Sep. 15, 2024

(30) Foreign Application Priority Data
Aug. 9, 2024 (TW) 113129879

(51) Int. Cl. H01L 29/423; H01L 21/8238; H01L 27/092; H01L 29/06; H01L 29/08; H01L 29/66; H01L 29/775; H01L 29/78; H01L 29/786

(52) U.S. Cl. CPC H10D 30/6735; H10D 30/014; H10D 30/0281; H10D 30/43; H10D 30/65; H10D 30/6757; H10D 62/121; H10D 62/151; H10D 84/0167; H10D 84/017; H10D 84/038; H10D 84/85

(57) ABSTRACT

A method for fabricating a semiconductor device includes the steps of first forming a channel structure on a substrate as the channel structure includes first semiconductor layers and second semiconductor layers alternately disposed over one another, forming a channel extension portion adjacent to the channel structure, forming a first gate structure on the channel structure and the channel extension portion, and then forming a first source/drain structure adjacent to the first gate structure.

### BACKGROUND OF THE INVENTION

### 1. Field of the Invention

The invention relates to a semiconductor device and fabrication method thereof, and more particularly to a semiconductor device combining nanowire transistor and lateral diffusion metal-oxide semiconductor (LDMOS) and fabrication method thereof.

### 2. Description of the Prior Art

In the past four decades, semiconductor industries keep downscaling the size of MOSFETs in order to achieve the goals of high operation speed and high device density. However, the reduction of device size won't last forever. When transistor shrink into or below 30 nm regime, leakage current due to severe short channel effects and thin gate dielectric causes the increase of off-state power consumption, and consequently causes functionality failure. One-dimensional devices based on nanowires or nanotubes are considered the immediate successors to replace the traditional silicon technology with relatively low technological risk. Nanowire transistor, which has higher carrier mobility and can be further enhanced by quantum confinement effect, is one of the most promising devices. In addition, the control of gate to channel can also be improved by using high-k dielectric layers.

### SUMMARY OF THE INVENTION

According to an embodiment of the present invention, a method for fabricating a semiconductor device includes the steps of first forming a channel structure on a substrate as the channel structure includes first semiconductor layers and second semiconductor layers alternately disposed over one another, forming a channel extension portion adjacent to the channel structure, forming a first gate structure on the channel structure and the channel extension portion, and then forming a first source/drain structure adjacent to the first gate structure.

According to another aspect of the present invention, a semiconductor device includes a channel structure on a substrate, a channel extension portion adjacent to the channel structure, a first gate structure on the channel structure and the channel extension portion, and a first source/drain structure adjacent to the first gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-10 illustrate a method for fabricating a nanowire transistor according to an embodiment of the present invention.

### DETAILED DESCRIPTION

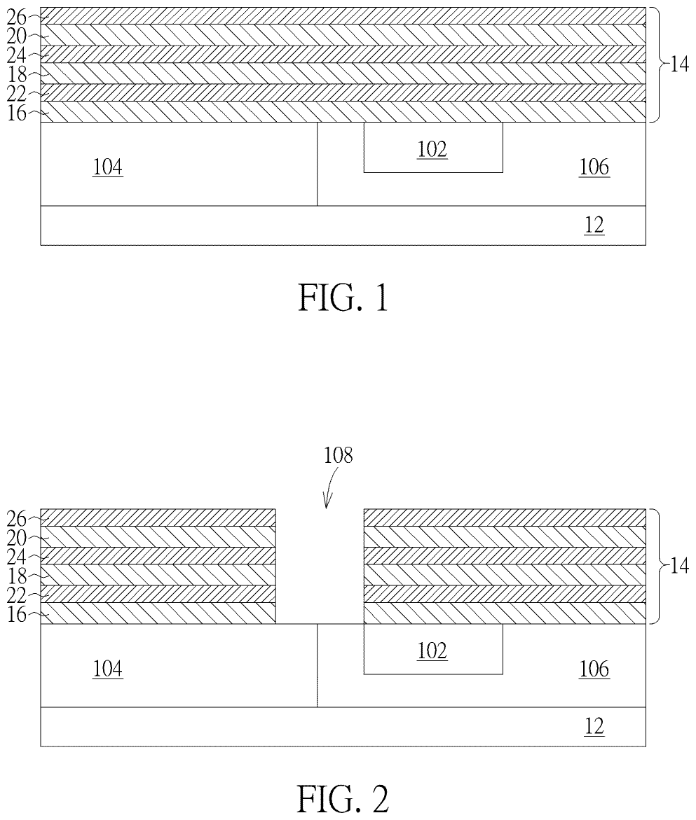

Referring to FIGS. 1-10, FIGS. 1-10 illustrate a method for fabricating a nanowire transistor according to an embodiment of the present invention. As shown in FIG. 1, a substrate 12 such as a silicon substrate is provided, a shallow trench isolation (STI) 102 is formed in the substrate 12, a well such as p-well 104 is formed adjacent to the STI 102, and a drift region such as a n-type drift region or n-drift region 106 is formed around the STI 102, in which the STI 102 preferably includes silicon oxide.

Next, a stack structure or channel structure 14 is formed on the substrate 12. In this embodiment, the channel structure 14 is preferably composed of a plurality of first semiconductor layers 16, 18, 20 and second semiconductor layers 22, 24, 26 stacked interchangeably or one over another. Preferably, the first semiconductor layers 16, 18, 20 and second semiconductor layers 22, 24, 26 are composed of different material or different lattice constant, in which the first semiconductor layers 16, 18, 20 and second semiconductor layers 22, 24, 26 could all be selected from the group consisting of silicon, germanium, doped silicon, doped germanium, and silicon germanium. In this embodiment, the first semiconductor layers 16, 18, 20 preferably include silicon germanium (SiGe) while the second semiconductor layers 22, 24, 26 include silicon, but not limited thereto. It should be noted that even though three layers of first semiconductor layers 16, 18, 20 and three layers of second semiconductor layers 22, 24, 26 are disclosed in this embodiment, the quantity of the first semiconductor layers 16, 18, 20 and second semiconductor layers 22, 24, 26 are not limited to the ones disclosed in this embodiment, but could all be adjusted according to the demand of the product.

Next, as shown in FIG. 2, a photo-etching process is conducted by using a patterned resist (not shown) as mask to remove part of the channel structure 14 for forming an opening 108 exposing the p-well 104 and n-drift region 106.

Next, as shown in FIG. 3, an epitaxial growth process is conducted to form a third semiconductor layer 110 in the opening 108, in which the third semiconductor layer 110 preferably constitutes a channel extension portion 112. In this embodiment, the second semiconductor layers 22, 24, 26 and the third semiconductor layer 110 are made of same material such as silicon. Nevertheless, according to other embodiment of the present invention, the third semiconductor layer 110 and the first semiconductor layers 16, 18, 20 could also include same material such as silicon germanium, which is also within the scope of the present invention.

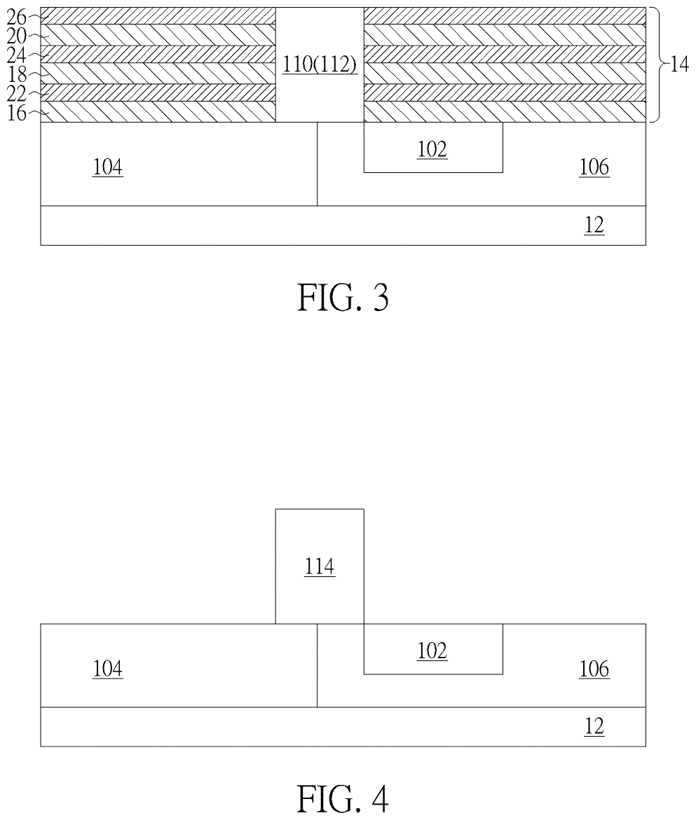

Referring to FIGS. 4-6, FIGS. 4-6 illustrate a method for fabricating the channel structure 14 according to another embodiment of the present invention. As shown in FIG. 4, in contrast to the aforementioned embodiment of first forming alternately stacked first semiconductor layers 16, 18, 20 and second semiconductor layers 22, 24, 26 and then patterning part of the second semiconductor layers 22, 24, 26 and part of the first semiconductor layers 16, 18, 20 through photo-etching process, the present embodiment could first form a patterned mask 114 on the substrate 12, in which the patterned mask 114 could overlap the p-well 104 and n-drift region 106 at the same time.

Next, as shown in FIG. 5, an epitaxial growth process is conducted to form alternately stacked channel structure 14 made of patterned first semiconductor layers 16, 18, 20 and patterned second semiconductor layers 22, 24, 26 adjacent to two sides of the patterned mask 114, and the patterned mask 114 is then removed thereafter to form an opening 108.

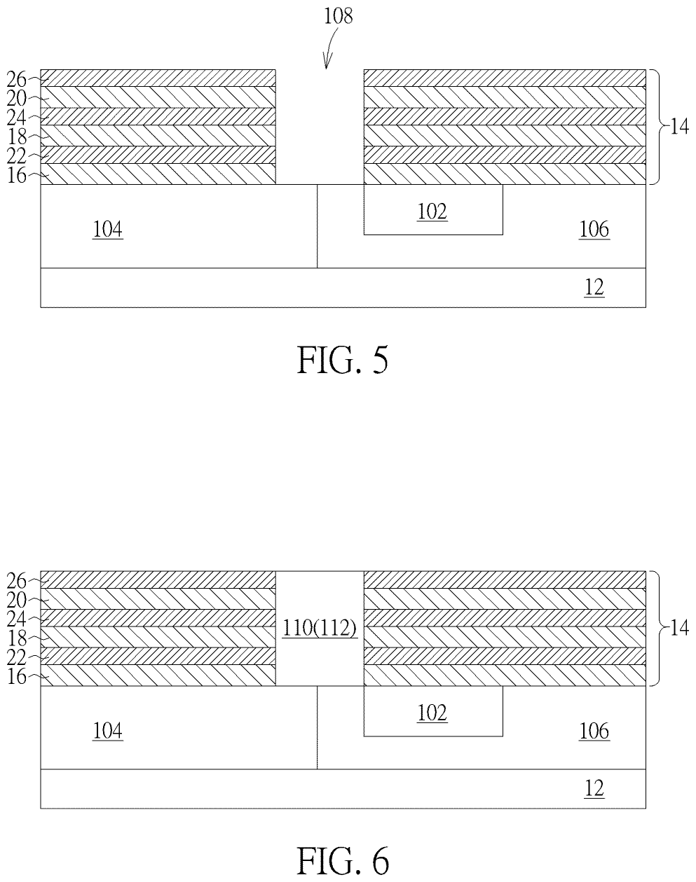

Next, as shown in FIG. 6, another epitaxial growth process is conducted to form a third semiconductor layer 110 in the opening 108 to serve as a channel extension portion 112. Similar to the aforementioned embodiment, the second semiconductor layers 22, 24, 26 and the third semiconductor layer 110 are made of same material such as silicon. Nevertheless, according to other embodiment of the present invention, the third semiconductor layer 110 and the first semiconductor layers 16, 18, 20 could also be made of same material such as silicon germanium, which is also within the scope of the present invention.

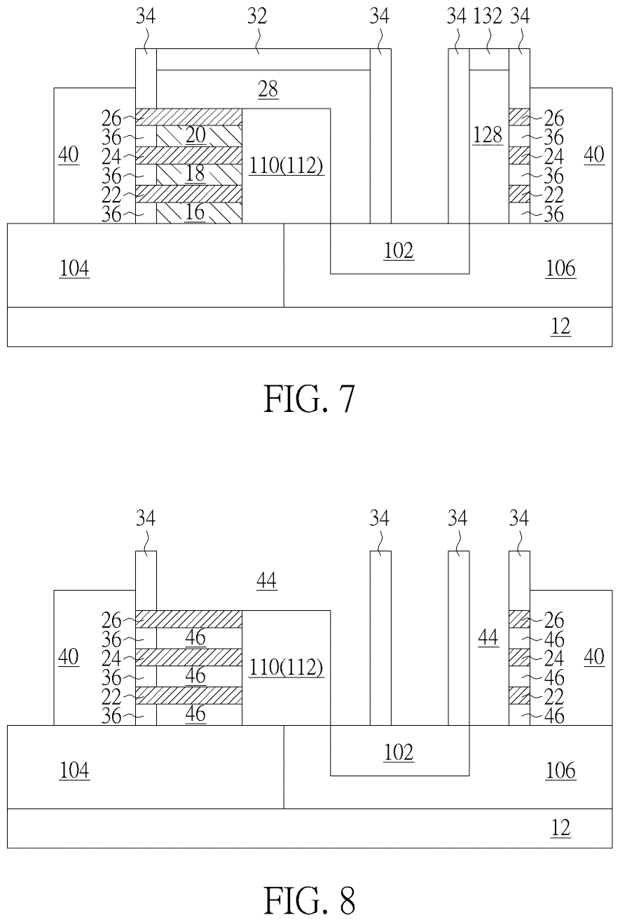

Next, as shown in FIG. 7, a photo-etching process is conducted to remove part of the channel structure 14, a gate structure 28 and selective hard mask 32 are formed on the channel structure 14 and channel extension portion 112 and another gate structure 128 and hard mask 132 are formed adjacent to the gate structure 28, a spacer 34 is formed adjacent to each of the gate structures 28, 128, part of the first semiconductor layers 16, 18, 20 are removed, and another spacer 36 is formed adjacent to the first semiconductor layers 16, 18, 20. Preferably, sidewalls of the spacers 36 are aligned with sidewalls of the second semiconductor layers 22, 24, 26 and the spacer 34 atop and the spacers 34, 36 could be made of same or different materials.

In this embodiment, the gate structures 28, 128 could be composed of polysilicon, the hard masks 32, 132 could include silicon nitride, and the spacers 34, 36 could be selected from the group consisting of SiO₂, SiN, SiON, and SiCN, but not limited thereto. It should be noted that even though each of the spacers 34 and 36 in this embodiment is a single layered spacer, it would also be desirable to form a composite spacer according to the demand of the product. For instance, each of the spacers 34, 36 could also be made of one or more spacers, in which the composite spacers could be made of same or different material. According to an embodiment of the present invention, a composite spacer could include a dual-layer spacer composed of both SiO₂ and SiN, or a triple-layer spacer composed of oxide-nitride-oxide, which are all within the scope of the present invention.

Next, a source/drain structure 40 is formed on the substrate 12 adjacent to two sides of the spacers 36 such as left side of the gate structure 28 and right side of the gate structure 128, in which the source/drain structure 40 could be made of semiconductor material or metal material. In this embodiment, if the source/drain structure 40 were made of semiconductor material, it could be selected from the group consisting of germanium, doped silicon, doped germanium, and silicon germanium. If the source/drain structure 40 were made of metal, it could be selected from the group consisting of W, Ti, TiN, Ta, TaN, and Al.

Next, as shown in FIG. 8, an etching process is conducted to remove the hard masks 32, 132 and the gate structures 28, 128 for forming recesses 44, and another selective etching process is conducted to remove the first semiconductor layers 16, 18, 20 for forming recesses 46. Since the first semiconductor layers 16, 18, 20 and the second semiconductor layers 22, 24, 26 are made of different material and a predetermined etching selectivity is found between the two semiconductor layers, it would be desirable to remove the first semiconductor layers 16, 18, 20 without damaging any of the second semiconductor layers 22, 24, 26 during the etching process.

According to an embodiment of the present invention, the first semiconductor layers 16, 18, 20 and the gate structures 28, 128 could also be made of same material. For instance, both the first semiconductor layers 16, 18, 20 and the gate structures 28, 128 could be made of polysilicon while the second semiconductor layers 22, 24, 26 is selected from the group consisting of silicon, germanium, doped silicon, doped germanium, and silicon germanium, and in such instance, only one single etching process is required to remove the hard masks 32, 132 and the first semiconductor layers 16, 18, 20 at the same time, which is also within the scope of the present invention. It should be noted that after removing the first semiconductor layers 16, 18, 20 through etching process, it would be desirable to selectively use an oxidation process or another etching process to remove part of the second semiconductor layers 22, 24, 26 so that the original cubic second semiconductor layers 22, 24, 26 are transformed into cylindrical nanowire channel layers, which is also within the scope of the present invention.

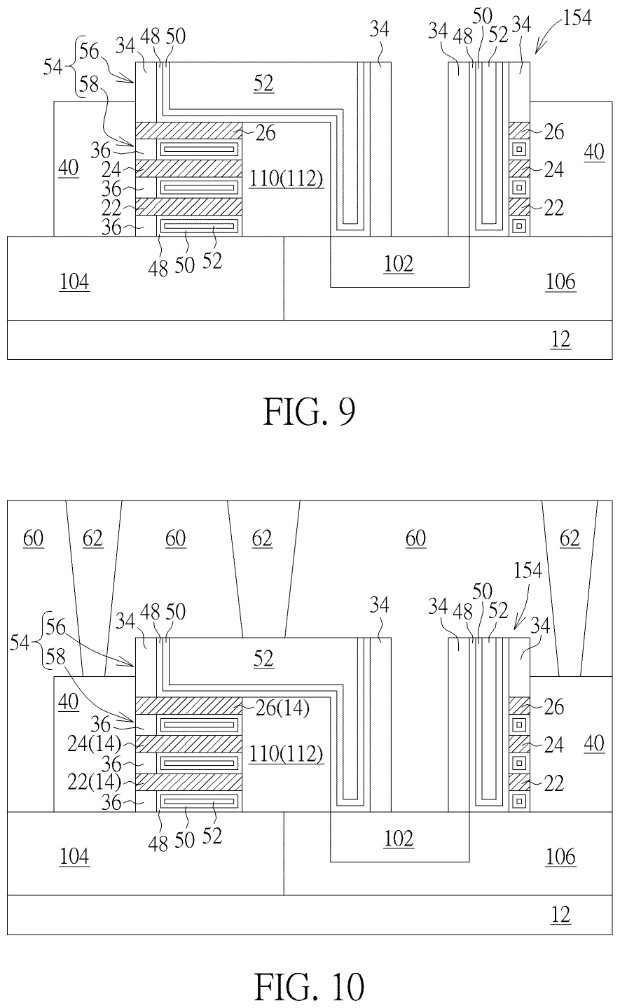

Next, as shown in FIG. 9, a high-k dielectric layer 48, a work function metal layer 50, and a low resistance metal layer 52 are formed in the recess 44 and recesses 46, and a planarizing process is conducted thereafter to form a gate structure 54 and another gate structure 154 adjacent to the gate structure 54. In this embodiment, the gate structure 54 preferably includes two parts, in which a first portion 56 is formed directly above the second semiconductor layers 22, 24, 26 while second portions 58 are formed in staggered arrangement or one over another with the second semiconductor layers 22, 24, 26. Preferably, each of the first portion 56 and the second portions 58 are made of the high-k dielectric layer 48, the work function metal layer 50, and the low resistance metal layer 52. Viewing from another perspective, the high-k dielectric layer 48 and the work function metal layer 50 are formed to wrap around the second semiconductor layers 22, 24, 26 while the low resistance metal layer 52 is formed to fill the recesses 44 and 46.

In this embodiment, the high-k dielectric layer 48 is preferably selected from dielectric materials having dielectric constant (k value) larger than 4. For instance, the high-k dielectric layer 48 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 50 is formed for tuning the work function of the later formed metal gates to be appropriate in an NMOS or a PMOS. For an NMOS transistor, the work function metal layer 50 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 50 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 50 and the low resistance metal layer 52, in which the material of the barrier layer may include titanium (Ti), titanium nitride (TiN), tantalum (Ta) or tantalum nitride (TaN). Furthermore, the material of the low-resistance metal layer 52 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity. Next, part of the high-k dielectric layer 48, part of the work function metal layer 50, and part of the low resistance metal layer 52 could be selectively removed to form a recess (not shown).

Next, as shown in FIG. 10, an inter-layer dielectric (ILD) layer 60 is formed on the source/drain structure 40 to fill the recess. Preferably, the ILD layer 60 could be made of any insulating material containing oxides such as an oxide layer made of tetraethyl orthosilicate (TEOS), but not limited thereto. Next, a contact plug formation process is conducted to form contact plugs 62 electrically connected to the source/drain structure 40. In this embodiment, the formation of the contact plugs 62 could be accomplished by using an etching process to remove part of the ILD layer 60 for forming contact holes (not shown) exposing the surface of source/drain structure 40. Next, a barrier layer and a metal layer are deposited to fill the contact holes completely, and a planarizing process such as chemical mechanical polishing (CMP) is conducted to remove part of the metal layer and part of the barrier layer for forming contact plugs 62 in the contact holes, in which the top surface of the contact plugs 62 is even with the top surface of the ILD layer 60. In this embodiment, the barrier layer is selected from the group consisting of Ti, Ta, TiN, TaN, and WN and the metal layer is selected from the group consisting of Al, Ti, Ta, W, Nb, Mo, and Cu, but not limited thereto. This completes the fabrication of a semiconductor device according to an embodiment of the present invention.

Referring again to FIG. 10, FIG. 10 further illustrates a structural view of a semiconductor device according to an embodiment of the present invention. As shown in FIG. 10, the semiconductor device includes a STI 102 disposed in the substrate 12, a p-well 104 disposed adjacent to the STI 102, a n-drift region 106 around the STI 102, a channel structure 14 disposed on the substrate 12, a channel extension portion 112 disposed adjacent to the channel structure 14, a gate structure 54 disposed on the channel structure 14 and the channel extension portion 112, another gate structure 154 disposed adjacent to the gate structure 54, and a source/drain structure 40 adjacent to the gate structures 54, 154. Preferably, the channel structure 14 includes second semiconductor layers 22, 24, 26 and metal layers such as work function metal layers 50 alternately disposed over one another, the channel extension portion 112 includes a third semiconductor layer 110, and the second semiconductor layers 22, 24, 26 and the third semiconductor layer 110 are made of same material such as silicon.

Specifically, the first portion 56 of the gate structure 54 is disposed on the channel structure 14 and extending to a top surface and sidewall of the channel extension portion 112, the first portion 56 includes a L-shape in a cross-section perspective, the second portion 58 of the gate structure 54 and the second semiconductor layers 22, 24, 26 of the channel structure 14 are stacked alternately, each of the gate structures 54, 154 include metal gates, and the channel extension portion 112 and the second semiconductor layers 22, 24, 26 of the channel structure 14 are made of same material such as silicon. Despite the channel extension portion 112 in this embodiment is disposed to overlap both the p-well 104 and n-drift region 106, according to other embodiment of the present invention, it would also be desirable to adjust the location of the boundary between the p-well 104 and the n-drift region 106 such that the boundary could be moved slightly to the left to be aligned with right sidewall of the channel structure 14. In other words, in this instance, the left sidewall of the channel extension portion 112 would be aligned with right sidewall of the p-well 104 such that the channel extension portion 112 only overlaps the n-drift region 106 but does not overlap the p-well 104, which is also within the scope of the present invention.

Overall, the present invention discloses an approach for integrating a nanowire transistor or a gate-all-around (GAA) transistor technique with a lateral diffusion metal-oxide semiconductor (LDMOS) device, which first forms a channel structure 14 on a substrate as the channel structure includes multiple first semiconductor layers and second semiconductor layers alternately disposed over one another, forms a channel extension portion 112 adjacent to the channel structure, forms a gate structure 28 on the channel structure and channel extension portion, and another gate structure 128 adjacent to the gate structure 28, and then forms a source/drain structure 40 on one side of the gate structure 28 and another side of the gate structure 128. Even though typical nanowire transistors have the advantage of better control in short channel effect (SCE) and lower leakage, they are still likely to cause damage in high voltage applications. By using the aforementioned approach of integrating applications in nanowire transistor and LDMOS device, the present invention is able to provide a means of lowering electrical field thereby improving breakdown voltage and Ioff current for transistors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a channel structure on a substrate, wherein the channel structure comprises first semiconductor layers and second semiconductor layers alternately disposed over one another;
forming a channel extension portion adjacent to the channel structure;
forming a first gate structure on the channel structure and the channel extension portion; and
forming a first source/drain structure adjacent to the first gate structure.

2. The method of claim 1, further comprising:
forming the first semiconductor layers and the second semiconductor layers on the substrate;
removing the first semiconductor layers and the second semiconductor layers to form an opening; and
forming a third semiconductor layer in the opening to form the channel extension portion.

3. The method of claim 2, wherein the second semiconductor layers and the third semiconductor layer comprise same material.

4. The method of claim 1, wherein top surfaces of the channel structure and the channel extension portion are coplanar.

5. The method of claim 1, further comprising:
forming a shallow trench isolation (STI) in the substrate;
forming a well region adjacent to the STI;
forming a drift region around the STI;
forming the channel structure and the channel extension portion on the well region;
forming the first gate structure on the channel structure;
forming a second gate structure on the drift region;
forming spacers adjacent to the first gate structure and the second gate structure;
forming the first source/drain structure adjacent to the first gate structure;
forming a second source/drain structure adjacent to the second gate structure;
removing the first gate structure and the second gate structure to form a first recess;
removing the first semiconductor layers to form a second recess between the second semiconductor layers; and
forming a work function metal layer in the first recess and the second recess.

6. The method of claim 5, wherein the well region and the drift region comprise different conductive type.

7. The method of claim 5, wherein the first gate structure overlaps the STI.

8. The method of claim 1, further comprising forming the first gate structure on the channel structure and a sidewall of the channel extension portion.

9. The method of claim 1, wherein the first gate structure comprises a L-shape.

10. A semiconductor device, comprising:
a channel structure on a substrate;
a channel extension portion adjacent to the channel structure;
a first gate structure on the channel structure and the channel extension portion; and
a first source/drain structure adjacent to the first gate structure.

11. The semiconductor device of claim 10, further comprising:
a shallow trench isolation (STI) in the substrate;
a well region adjacent to the STI;
a drift region around the STI;
the channel structure and the channel extension portion on the well region the first gate structure on the nanowire structure and the channel extension portion;
a second gate structure on the drift region;
the first source/drain structure adjacent to the first gate structure; and
a second source/drain structure adjacent to the second gate structure.

12. The semiconductor device of claim 11, wherein the well region and the drift region comprise different conductive type.

13. The semiconductor device of claim 11, wherein the first gate structure overlaps the STI.

14. The semiconductor device of claim 10, wherein the first gate structure is on the channel structure and a sidewall of the channel extension portion.

15. The semiconductor device of claim 10, wherein the first gate structure comprises a L-shape.

16. The semiconductor device of claim 10, wherein the first gate structure comprises a metal gate.

17. The semiconductor device of claim 10, wherein the channel structure comprises first semiconductor layers and metal layers alternately disposed over one another.

18. The semiconductor device of claim 17, wherein the channel extension portion comprises a second semiconductor layer.

19. The semiconductor device of claim 18, wherein the first semiconductor layers and the second semiconductor layer comprise same material.
